(19) United States
(12) Patent Application Publication
(10) Pub. No.: US 2009/0315064 A1
(43) Pub. Date: Dec. 24, 2009

(54) Light emission device

(76) Inventor: Chih-Yang Wang, San Chung City (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 12/318,171

(22) Filed: Dec. 23, 2008

(30) Foreign Application Priority Data
Jun. 24, 2008 (TW) 097211139

(51) Int. Cl. H01L 33/00

(52) U.S. Cl. 257/99; 257/E33.062

(57) ABSTRACT

A light emission device includes a substrate, at least one light-emitting diode (LED), and a plurality of electrical connection elements. The substrate defines a plurality of pilot holes, each having a conductive layer formed in a circumference thereof. The LED is set on the substrate and has a plurality of terminals each forming a through hole corresponding to a respective pilot hole of the substrate. Each electrical connection element is arranged between the conductive layer of each pilot hole of the substrate and each terminal of the LED. The electrical connection element is molten by being heated to form an electric connection portion, which attaches to the conductive layer of the pilot hole and the terminal of the light-emitting diode. In this way, precise positioning between the substrate and the LED is realized, bonding strength is enhanced, and overall thickness is reduced.

### FIELD OF THE INVENTION

The present invention relates to a light emission device, and in particular to a light emission device comprising a combination of a substrate, at least one light-emitting diode (LED), and a plurality of electrical connection elements, wherein an electric connection portion is formed to cover a conductive layer on a circumference and inside surface of each pilot hole and an inside surface of a through hole of each terminal of the LED for being applicable to all sorts of assembly of LED and substrate or the likes.

### BACKGROUND OF THE INVENTION

A conventional light-emitting diode (LED) based light emission device mounts an LED to a circuit board to form an illuminating device or a lighting device, which is applicable to an electronic device. However, the current trend of the high-precision electronic devices is to get compact and slim. This makes the available interior space of a high-precision electronic device very limited and thus, positional precision of the light emission device to be applied therein is of severe requirement. Conventionally, when an LED is mounted to a circuit board, improper or inaccurate soldering of the terminals of the LED to the circuit board often leads to the LED shifting from a desired position, thereby deteriorating the overall positional or dimensional precision, which prevents the light emission device for being used in a precision electronic device.

Further, mounting an LED to a circuit board is often carried out by soldering that is realized through high temperature generated by a soldering pot. However, in a mass production process, the amount of solder cannot be easily controlled. An excessive amount of solder raises the LED upward, while insufficient amount of solder may lead to false soldering or missing solder, which increases flaw rate, making mass production very difficult and making it not easy to meet the requirement of being compact and slim. Apparently, a solution to such problems is desired.

### SUMMARY OF THE INVENTION

An objective of the present invention is to provide a light emission device, which comprises a combination of a substrate, at least one light-emitting diode (LED), and a plurality of electrical connection elements, in which the substrate forms a plurality of pilot holes, the LED has a plurality of terminals each forming a through hole, and each electrical connection element is molten by being heated to form an electric connection portion, which drags the terminal of the LED and the pilot hole of the substrate to correspond to each other for realizing precise positioning between the substrate and the LED thereby enhancing practicability of the present invention.

Another objective of the present invention is to provide a light emission device, which comprises a combination of a substrate, at least one LED, and a plurality of electrical connection elements, in which the substrate forms a plurality of pilot holes, the LED has a plurality of terminals each forming a through hole, and each electrical connection element is molten by being heated to form an electric connection portion to reduce the thickness of the connection between the substrate and the LED for making the entirety of the device compact and slim thereby enhancing convenience of the present invention.

A further objective of the present invention is to provide a light emission device, which comprises a combination of a substrate, at least one LED, and a plurality of electrical connection elements, in which the substrate forms a plurality of pilot holes, the LED has a plurality of terminals each forming a through hole, and each electrical connection element is molten by being heated to form an electric connection portion, which attaches to a conductive layer formed in a circumference of each pilot hole and each terminal of the LED so as to improve bonding strength between the substrate and the LED thereby enhancing practicability of the present invention.

To realize the above objectives, the present invention provides a light emission device that comprises a substrate, at least one light-emitting diode (LED), and a plurality of electrical connection elements. The substrate defines a plurality of pilot holes, each having a conductive layer formed in a circumference thereof. The LED is set on the substrate and has a plurality of terminals each forming a through hole corresponding to a respective pilot hole of the substrate. Each electrical connection element is arranged between the conductive layer of each pilot hole of the substrate and each terminal of the LED. The electrical connection element is molten by being heated to form an electric connection portion, which attaches to the conductive layer of the pilot hole and the terminal of the light-emitting diode. In this way, precise positioning between the substrate and the LED is realized, bonding strength is enhanced, and overall thickness is reduced.

### BRIEF DESCRIPTION OF THE DRAWINGS

The present invention will be apparent to those skilled in the art by reading the following description of preferred embodiments thereof with reference to the drawings, in which:

FIG. 1 is a perspective view illustrating a light emission device in accordance with the present invention;

FIG. 2 is an exploded view of the light emission device of the present invention

FIG. 3 is a cross-sectional view illustrating an embodiment of the light emission device in accordance with the present invention;

FIG. 4 is a perspective view illustrating the operation of the light emission device of the present invention;

FIG. 5 is a perspective view illustrating a light emission device in accordance with another embodiment of the present invention;

FIG. 6 is an exploded view of the light emission device of said another embodiment of the present invention; and

FIG. 7 a cross-sectional view illustrating the light emission device of said another embodiment of the present invention.

### DETAILED DESCRIPTION OF THE PREFERRED EMBODIMENTS

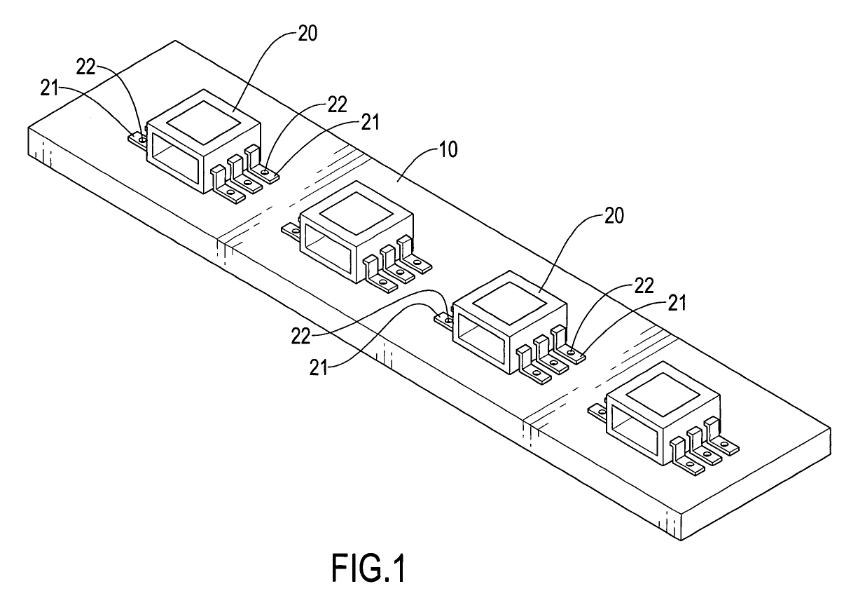

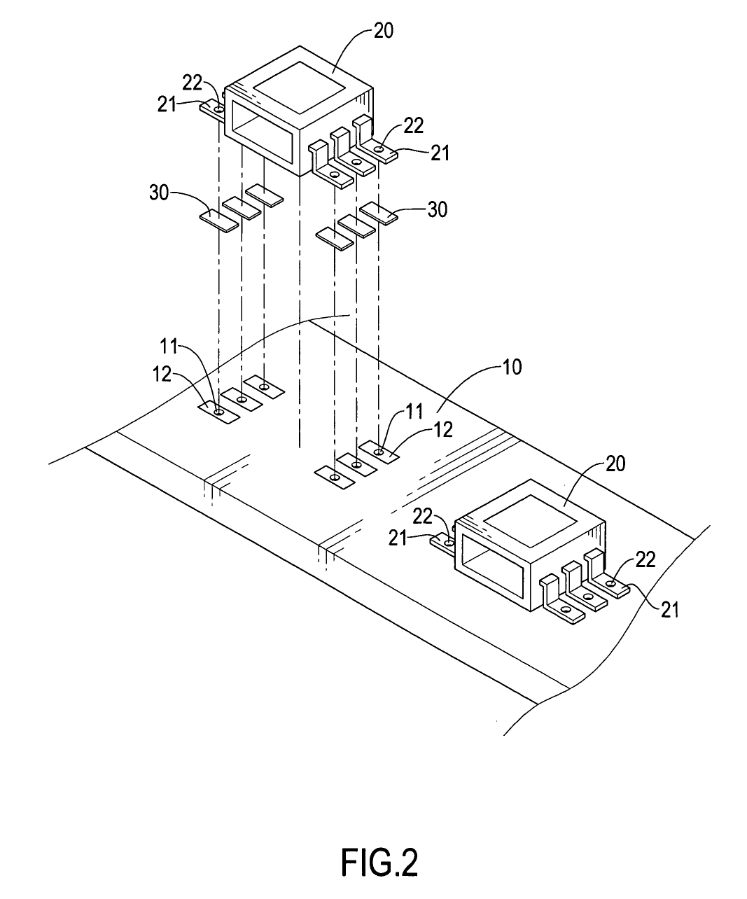

With reference to FIGS. 1-3, the present invention provides a light emission device, which comprises the following constituent elements/components:

A substrate 10, which comprises a printed circuit board in the instant embodiment, but can be any one of a ceramic substrate, a silicon substrate, an aluminum substrate, a flexible printed circuit board (all not shown), forms a plurality of pilot holes 11, each being a through hole defined in the substrate 10. Each pilot hole 11 is provided with a conductive layer 12 arranged along a circumference of the pilot hole 11. The conductive layer 12 is formed on an inside surface of the pilot hole 11 and a circumferential area around upper and lower openings of the pilot hole 11. In the instant embodiment, the pilot hole 11 is embodied as a through hole extending through the substrate 10, but the pilot hole 11 may also be embodied as a blind hole defined in but not extending through the substrate 10 with the conductive layer 12 formed on the inside surface of the pilot hole 11 and a circumferential area around an upper opening of the pilot hole 11.

At least one light-emitting diode (LED) 20, which in the instant embodiment comprises a single LED 20, but may also comprise a plurality of LEDs 20, is set on the substrate 10. The LED 20 has a plurality of terminals 21. Each terminal 21 forms a through hole 22, which is positioned to correspond to a respective one of the pilot holes 11 of the substrate 10.

A plurality of electrical connection elements 30, which may comprise solder (or may be any one of for example tin, silver, copper, gold, and nickel alloy), is respectively arranged between the conductive layer 12 of each pilot hole 11 of the substrate 10 and the associated terminal 21 of the LED 20 for each forming an electric connection portion 31 when the electrical connection element 30 is heated. The electric connection portion 31 is spread and attaches to the conductive layer 12 in the circumference of each pilot hole 11 and covers an inside surface of the through hole 22 of each terminal 21 of the LED 20 to ensure a firm connection.

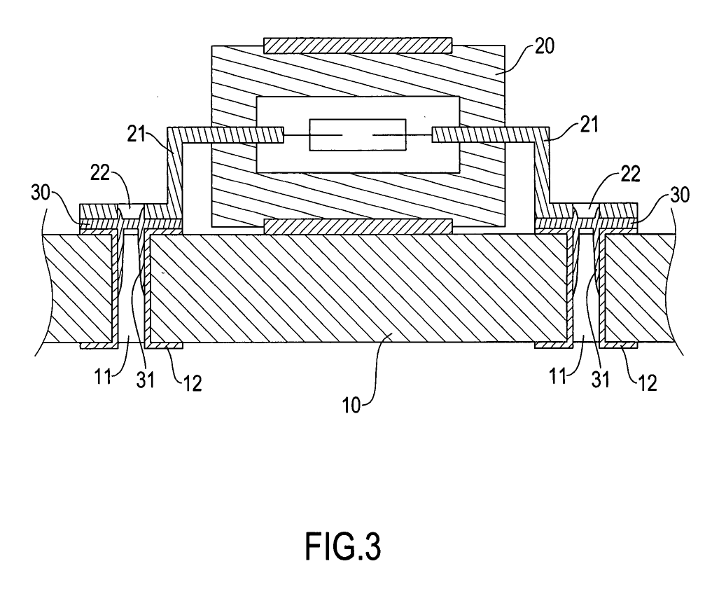

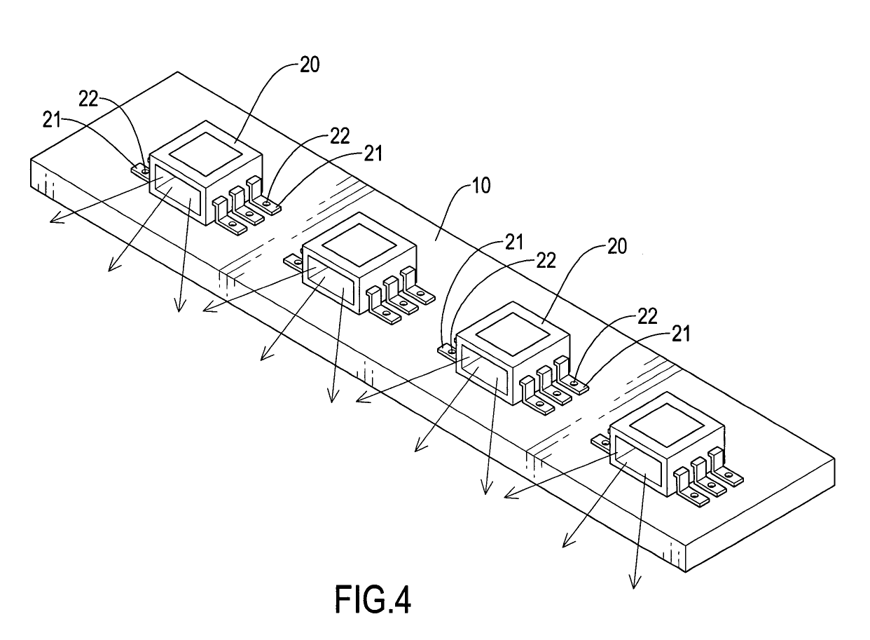

Referring to FIGS. 3 and 4, which illustrate an embodiment of the present invention, the through hole 22 of each terminal 21 of the LED 20 is positioned to correspond to the respective pilot hole 11 of the substrate 10. When the electrical connection element 30 is heated, the high temperature process makes the electrical connection element 30 molten. The molten electrical connection element 30 is caused by gravity or by means of diffusion to flow into the pilot hole 11 of the substrate 10 and meanwhile, due to the viscous force acting between the molten electrical connection element 30 and the inside surface of the through hole of each terminal 21 of the LED 20, the LED 20 is dragged by the flow of the molten electrical connection element 30 to approach the substrate 10 and at the same time, the molten electrical connection element 30 covers and attaches to the inside surface of the through hole 22 of the terminal 21. After the electrical connection element 30 is cooled down and solidifies, an electric connection portion 31 is formed. The electric connection portion 31 helps to increase the contact area between the LED 20 and the substrate 10, making firm connection between the LED 20 and the substrate 10. Further, precise positioning of each terminal 21 of the LED 20 can be realized since the terminal 21 is provided with a through hole 22 that is set to correspond in position to the respective pilot hole 11 of the substrate 10, whereby automatic correction of positional shifting caused by incorrect/inaccurate positioning of the LED 20 in the manufacturing process can be effected and thickness of connection between the substrate 10 and the LED 20 can be reduced.

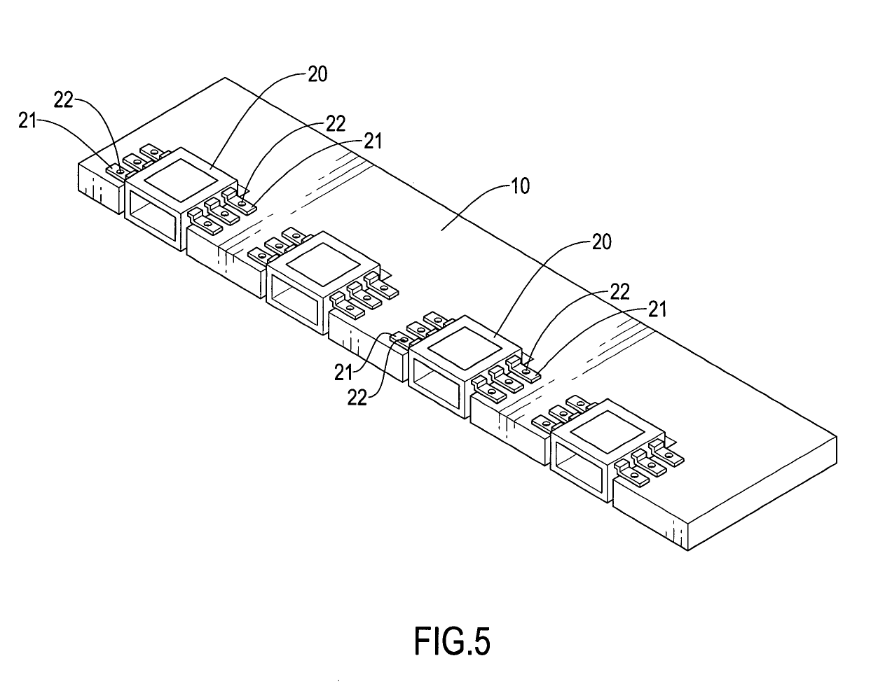

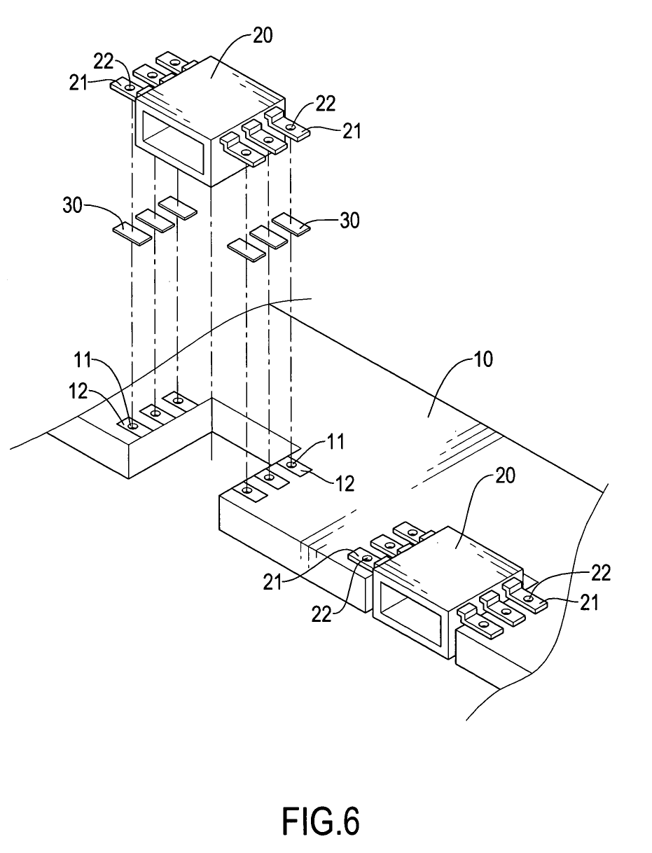

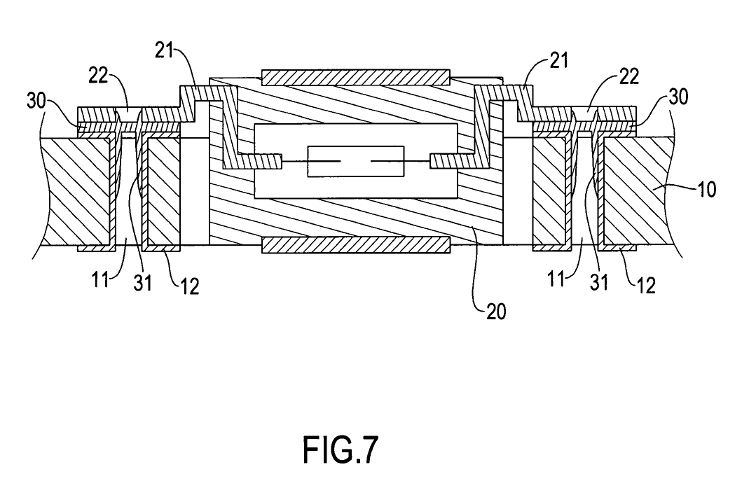

Referring to FIGS. 5-7, which illustrates another embodiment of the present invention, in this another embodiment, the substrate 10 forms at least one notch 13 in a side edge of the substrate 10. (In the instant embodiment, a plurality of notches 13 is formed to respectively correspond to a plurality of LEDs 20.) The LED 20 is set in a respective notch 13 formed in the side edge of the substrate 10. The pilot holes 11 of the substrate 10 are respectively formed at opposite banks of each notch 13 with the terminals 21 of the LED 20 positioned on the pilot holes 11 of the two banks of the notch 13. When each electrical connection element 30 is heated, the high temperature process makes the electrical connection element 30 molten. The molten electrical connection element 30 is caused by gravity or by means of diffusion to flow into the pilot hole 11 of the substrate 10 and meanwhile, due to the viscous force acting between the molten electrical connection element 30 and the inside surface of the through hole of each terminal 21 of the LED 20, the LED 20 is dragged by the flow of the molten electrical connection element 30 to approach the substrate 10 and the molten electrical connection element 30 covers and attaches to the inside surface of the through hole 22 of the terminal 21. After the electrical connection element 30 is cooled down and solidifies, an electric connection portion 31 is formed. The electric connection portion 31 helps to increase the contact area between the LED 20 and the substrate 10, making firm connection between the LED 20 and the substrate 10. Further, precise positioning of each terminal 21 of the LED 20 can be realized since the terminal 21 is provided with a through hole 22 that is set to correspond in position to the respective pilot hole 11 of the substrate 10, whereby automatic correction of positional shifting caused by incorrect/inaccurate positioning of the LED 20 in the manufacturing process can be effected and an overall thickness of entire light emission device can be reduced.

Referring to FIGS. 1-7, the features of the present invention are that a combination of a substrate 10, at least one LED 20, and a plurality of electrical connection elements 30 is provided, in which the substrate 10 forms a plurality of pilot holes 11 each provided with a conductive layer 12 in a circumference thereof; the at least one LED 20 is set on the substrate 10 with a through hole 22 of each terminal 21 of the LED 20 corresponding in position to each pilot hole 11 of the substrate 10; and an electrical connection element 30 is subjected to a heating process to form an electric connection portion 31 in such a way that the flow of molten electrical connection element 30 drags each terminal 21 of the at least one LED 20 to correspond to the respective pilot hole 11 of the substrate 10 and the electric connection portion 31 is spread over and attaches to the conductive layer 12 in the circumference of each pilot hole 11 of the substrate 10 and further covers and attaches to the inside surface of the through hole 22 of each terminal 21 of the at least one LED 20. In this way, precise positioning between the substrate 10 and the LED 20 is realized and the thickness of connection between the substrate 10 and the LED 20 is reduced and further the bonding strength between the substrate 10 and the at least one LED 20 is also enhanced to thereby improve the practicability and convenience of the present invention.

Although the present invention has been described with reference to the preferred embodiments thereof, it is apparent to those skilled in the art that a variety of modifications and changes may be made without departing from the scope of the present invention which is intended to be defined by the appended claims.

What is claimed is:

1. A light emission device, comprising:
a substrate, which defines a plurality of pilot holes, each pilot hole having a conductive layer formed in a circumference thereof;
at least one light-emitting diode, which is set on the substrate, the at least one light-emitting diode having a plurality of terminals each forming a through hole, which corresponds to a respective pilot hole of the substrate; and
a plurality of electrical connection elements, each of which is arranged between the conductive layer of each pilot hole of the substrate and each terminal of the light-emitting diode, whereby the electrical connection element is meltable by being subjected to heating for forming an electric connection portion, the electric connection portion attaching to the conductive layer of the circumference of the pilot hole and the terminal of the light-emitting diode.

2. The light emission device as claimed in claim 1, wherein the substrate comprises one of a printed circuit board, a ceramic substrate, a silicon substrate, an aluminum substrate and a flexible circuit board.

3. The light emission device as claimed in claim 1, wherein the electrical connection element comprises one of solder, tin, sliver, gold, copper, and nickel alloy.

4. The light emission device as claimed in claim 1, wherein the substrate has a side edge in which at least one notch is defined, the light-emitting diode being received in the notch, the plurality of pilot holes of the substrate being respectively formed in opposite banks of the notch, the terminals of the light-emitting diode being positioned on the pilot holes on the opposite banks.

5. The light emission device as claimed in claim 1, wherein the electric connection portion is spread over and attaches to the conductive layer of the circumference of the pilot hole of the substrate and covers and attaches to an inside surface of the through hole of the terminal of the light-emitting diode.

6. The light emission device as claimed in claim 1, wherein the pilot hole comprises a hole defined through the substrate, the conductive layer being formed on an inside surface of the pilot hole and circumferential areas around upper and lower openings of the pilot hole.

7. The light emission device as claimed in claim 1, wherein the pilot hole comprises a blind hole defined in the substrate, the conductive layer being formed on an inside surface of the pilot hole and a circumferential area around an upper opening of the pilot hole.
